(19) United States
(12) Patent Application Publication
(10) Pub. No.: US 2025/0380531 A1
(43) Pub. Date: Dec. 11, 2025

(54) LIGHT RECEIVING DEVICE

(71) Applicant: SUMITOMO ELECTRIC INDUSTRIES, LTD., Osaka (JP)

(72) Inventors: Kazutoshi NATSUME, Osaka-shi (JP); Ryo SUGAHARA, Osaka-shi (JP)

(73) Assignee: SUMITOMO ELECTRIC INDUSTRIES, LTD., Osaka (JP)

(21) Appl. No.: 19/201,303

(22) Filed: May 7, 2025

(30) Foreign Application Priority Data
Jun. 6, 2024 (JP) 2024-092166

(51) Int. Cl. H10F 77/14; H10F 30/225; H10F 77/124

(52) U.S. Cl. CPC H10F 77/147; H10F 30/225; H10F 77/1248

(57) ABSTRACT

A light receiving device includes a first semiconductor layer having a first conductivity type, a light-absorbing layer stacked over a surface of the first semiconductor layer, a second semiconductor layer stacked over a surface of the light-absorbing layer opposite to the first semiconductor layer, a third semiconductor layer stacked on a surface of the second semiconductor layer opposite to the light-absorbing layer and having a second conductivity type, a first electrode electrically connected to the first semiconductor layer, and a second electrode electrically connected to the third semiconductor layer. The second semiconductor layer is configured to form a mesa and is thicker than the light-absorbing layer.

### CROSS REFERENCE TO RELATED APPLICATIONS

This application claims priority based on Japanese Patent Application No. 2024-092166 filed on Jun. 6, 2024, and the entire contents of the Japanese patent application are incorporated herein by reference.

### TECHNICAL FIELD

The present disclosure relates to a light receiving device.

### BACKGROUND

In a light receiving device, a mesa is formed to separate elements (for example, patent literature 1: Japanese Unexamined Patent Application Publication No. 2005-328036).

### SUMMARY

A light receiving device according to the present disclosure includes a first semiconductor layer having a first conductivity type, a light-absorbing layer stacked over a surface of the first semiconductor layer, a second semiconductor layer stacked over a surface of the light-absorbing layer opposite to the first semiconductor layer, a third semiconductor layer stacked on a surface of the second semiconductor layer opposite to the light-absorbing layer and having a second conductivity type, a first electrode electrically connected to the first semiconductor layer, and a second electrode electrically connected to the third semiconductor layer. The second semiconductor layer is configured to form a mesa and is thicker than the light-absorbing layer.

### BRIEF DESCRIPTION OF THE DRAWINGS

FIG. 1 is a plan view illustrating a light receiving device according to an embodiment.

FIG. 2 is a cross-sectional view illustrating the light receiving device.

FIG. 3 is a cross-sectional view illustrating the light receiving device.

FIG. 4 is a diagram illustrating a capacitance of the light receiving device.

FIG. 5 is a diagram illustrating an operating voltage of the light receiving device.

FIG. 6 is a cross-sectional view illustrating the light receiving device according to a second embodiment.

FIG. 7 is a diagram illustrating an electric field strength.

FIG. 8 is a diagram illustrating a thickness of a depletion layer.

FIG. 9 is a diagram illustrating the capacitance of the light receiving device.

FIG. 10 is a diagram illustrating the operating voltage of the light receiving device.

### DETAILED DESCRIPTION

In order to expand the operating band of the light receiving device, the element capacitance needs to be decreased. A cap layer is stacked on the light-absorbing layer. The capacitance of the light receiving device decreases as the cap layer becomes depleted. By forming the mesa in the cap layer, element isolation is also possible. Meanwhile, a high electric field is applied to a side surface of the mesa. By applying a high electric field to the light-absorbing layer, a tunnel current increases because of a narrow band gap of the light-absorbing layer. Thus, an object of the present disclosure is to provide the light receiving device that can decrease the capacitance and reduce the electric field.

### DESCRIPTION OF EMBODIMENTS OF PRESENT DISCLOSURE

First, the contents of embodiments of the present disclosure will be listed and explained.

(1) A light receiving device according to one aspect of the present disclosure includes a first semiconductor layer having a first conductivity type, a light-absorbing layer stacked over a surface of the first semiconductor layer, a second semiconductor layer stacked over a surface of the light-absorbing layer opposite to the first semiconductor layer, a third semiconductor layer stacked on a surface of the second semiconductor layer opposite to the light-absorbing layer and having a second conductivity type, a first electrode electrically connected to the first semiconductor layer, and a second electrode electrically connected to the third semiconductor layer. The second semiconductor layer is configured to form a mesa and is thicker than the light-absorbing layer. Since the thick second semiconductor layer is depleted, the capacitance decreases. Since the electric field is dispersed to the side surface of the thick second semiconductor layer, the electric field applied to the light-absorbing layer can be reduced.

(2) In the above (1), the second semiconductor layer may have a thickness of 1.0 μm to 3.4 μm. The capacitance can be decreased.

(3) In the above (1) or (2), the second semiconductor layer may be undoped. Since a depletion region spreads in the undoped second semiconductor layer, capacitance can be decreased. Since the electric field is dispersed to the side surface of the second semiconductor layer, the concentration of the electric field in the light-absorbing layer may be alleviated.

(4) In the above (1) or (2), the second semiconductor layer may have the second conductivity type, and the second semiconductor layer may have an impurity concentration lower than an impurity concentration of the third semiconductor layer. The electric field is uniformly applied to the side surface of the mesa. The electric field applied to the light-absorbing layer can be reduced.

(5) In the above (4), the second semiconductor layer may have an impurity concentration of 1.0×10¹⁵ cm⁻³ to 1.0×10¹⁷ cm⁻³. The electric field is dispersed over the side surfaces of the mesa. The electric field strength in the second semiconductor layer is attenuated, and the total amount of the electric field applied to the second semiconductor layer, that is, the voltage can be reduced. Both the capacitance and the operating voltage can be decreased, and the power consumption can be lowered.

(6) In any one of the above (1) to (5), the second semiconductor layer may include a first portion and a second portion, the first portion of the second semiconductor layer may be configured to form the mesa, and the second portion of the second semiconductor layer, the light-absorbing layer, and the first semiconductor layer may be located below the mesa and outside the mesa. The electric field is dispersed on the side surface of the mesa and is less likely to concentrate below the mesa. The electric field distribution of the light-absorbing layer is uniformed, and the electric field is less likely to be concentrated.

(7) In any one of the above (1) to (6), the light-absorbing layer may be formed of indium gallium arsenide, and the second semiconductor layer may be formed of aluminum indium arsenide. The second semiconductor layer has the wider band gap than the light-absorbing layer. By dispersing the electric field to the thick second semiconductor layer, the electric field applied to the light-absorbing layer having a low band gap is reduced.

(8) In any one of the above (1) to (7), the light receiving device may be an avalanche photodiode, and the light receiving device may include a multiplication layer stacked below the light-absorbing layer. The operating voltage can be lowered and the capacitance can be decreased.

### DETAILS OF EMBODIMENTS OF PRESENT DISCLOSURE

Specific examples of the light receiving device according to the embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

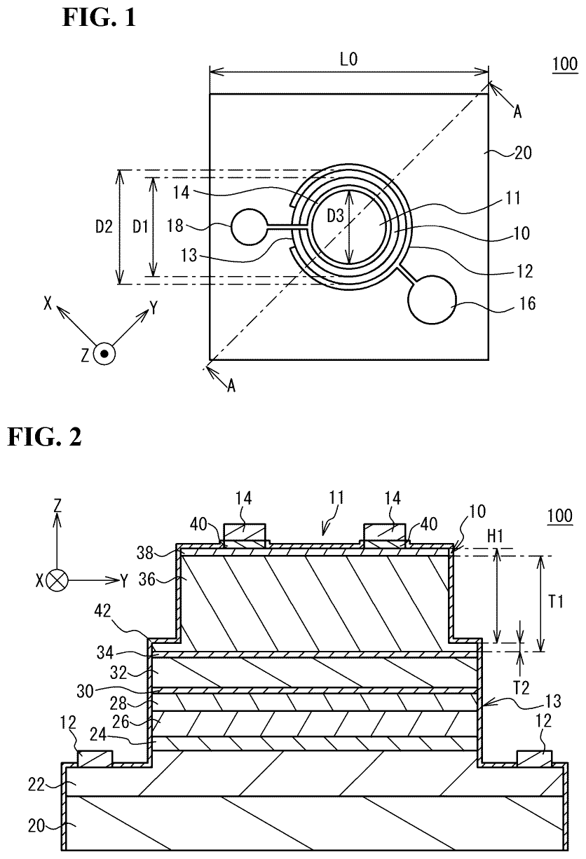

FIG. 1 is a plan view illustrating a light receiving device 100 according to a first embodiment. An insulation film described later is seen through. FIG. 2 is a cross-sectional view illustrating the light receiving device 100, showing a cross-section along line A-A in FIG. 1. The light receiving device 100 is an avalanche photodiode (APD) and is used for detecting near-infrared light.

As shown in FIG. 1, the light receiving device 100 has a mesa 10, a mesa 13, an electrode 12 (first electrode), an electrode 14 (second electrode), a pad 16, a pad 18, and a substrate 20. The substrate 20 has, for example, a square planar shape. A top surface of the substrate 20 is parallel to a XY plane. A length L0 of one side is, for example, 400 μm. A Z axis is the thickness direction of the substrate 20. An X axis, a Y axis, and the Z axis are orthogonal to each other.

In a plan view, the mesa 10 and the mesa 13 are circular. The mesa 10 and the mesa 13 are arranged, for example, concentrically. The mesa 13 is larger than the mesa 10. The mesa 10 is located inside the mesa 13. A diameter D1 of the mesa 10 is, for example, 240 μm. A diameter D2 of the mesa 13 is, for example, 280 μm.

The electrode 12 and the electrode 14 have an annular shape. The electrode 14 is provided on the mesa 10. A part of mesa 10 inside the electrode 14 functions as a light receiving region 11. A diameter D3 of the light receiving region 11 is, for example, 200 μm. The electrode 12 is provided outside the mesa 10 and the mesa 13, and surrounds the mesa 10 and the mesa 13. The Pad 16 is electrically connected to the electrode 12. The Pad 18 is electrically connected to the electrode 14.

As shown in FIG. 2, the light receiving device 100 has the substrate 20, a semiconductor layer 22, a semiconductor layer 24, a multiplication layer 26, an electric field adjusting layer 28, a current diffusion layer (CSL) 30, a light-absorbing layer 32, a current diffusion layer 34, a cap layer 36 (second semiconductor layer), a semiconductor layer 38, and a contact layer 40. The semiconductor layer 22 and the semiconductor layer 24 correspond to the first semiconductor layer. The semiconductor layer 38 and the contact layer 40 correspond to the third semiconductor layer.

The center portion of the substrate 20 in the XY plane protrudes in the Z axis direction from an outer peripheral portion of the substrate 20. The semiconductor layer 22, the semiconductor layer 24, the multiplication layer 26, the electric field adjusting layer 28, the current diffusion layer 30, the light-absorbing layer 32, the current diffusion layer 34, and the cap layer 36 are sequentially stacked on a protruding portion of the substrate 20, and these layers form the mesa 13. A center portion of the cap layer 36 protrudes in the Z axis direction from an outer peripheral portion of the cap layer 36. The semiconductor layer 38 is stacked on the protruding portion of the cap layer 36. The cap layer 36 and the semiconductor layer 38 form the mesa 10. The side surfaces of the cap layer 36 and the semiconductor layer 38 are side surfaces of the mesa 10. A height H1 from the top surface of the outer peripheral portion of the cap layer 36 to the top surface of the mesa 10 is, for example, 2000 nm.

The annular contact layer 40 is provided on a top surface of the semiconductor layer 38. An insulation film 42 covers the top surface of the substrate 20, the side surface and a top surface of the mesa 13, and the side surface and the top surface of the mesa 10. An opening is provided in the part of the insulation film 42 that covers the top surface of the mesa 10. The annular electrode 14 is provided in the opening and electrically connected to the contact layer 40. An opening is provided in the part of the insulation film 42 that covers the top surface of the substrate 20. The electrode 12 is provided in the opening and electrically connected to the semiconductor layer 22.

The substrate 20 is, for example, a semi-insulating semiconductor substrate and is formed of indium phosphide (InP) doped with iron (Fe). The semiconductor layer 22 is formed of, for example, an n-type (first conductivity type) indium gallium arsenide (n-InGaAs). The thickness of the semiconductor layer 22 is, for example, 1500 nm. The semiconductor layer 22 is doped with impurities such as silicon (Si). An impurity concentration is, for example, 3.5×10¹⁸ cm⁻³. The semiconductor layer 24 is formed of, for example, an n-type aluminum indium arsenide (n-AlInAs). The thickness of the semiconductor layer 24 is, for example, 700 nm. The semiconductor layer 24 is doped with, for example, Si. An impurity concentration is, for example, 2.0×10¹⁸ cm⁻³.

The multiplication layer 26 is formed of, for example, undoped AlInAs (i-AlInAs). The thickness of the multiplication layer 26 is, for example, 600 nm. The electric field adjusting layer 28 is formed of, for example, a p⁻-type (second conductivity type) AlInAs ((p⁻)-AlInAs). The thickness of the electric field adjusting layer 28 is, for example, 100 nm. The electric field adjusting layer 28 is doped with impurities such as beryllium (Be). An impurity concentration is, for example, 2.8×10¹⁷ cm⁻³.

The current diffusion layer 30 and the current diffusion layer 34 are formed of, for example, undoped indium aluminum gallium arsenide (i-InAlGaAs). Each thickness of the current diffusion layer 30 and the current diffusion layer 34 is, for example, 50 nm. The light-absorbing layer 32 is formed of undoped indium gallium arsenide (i-InGaAs). The thickness of the light-absorbing layer 32 is, for example, 1000 nm. Impurities are unintentionally contained in an undoped semiconductor layer in some cases. The light-absorbing layer 32 has an impurity concentration of 1.0×10¹⁵ cm⁻³ or less.

The cap layer 36 is formed of, for example, undoped AlInAs (i-AlInAs). The cap layer 36 is thicker than the light-absorbing layer 32. A thickness T1 of the cap layer 36 is, for example, 2500 nm. A thickness T2 of the cap layer 36 at the position outside the mesa 10 is, for example, 700 nm. A band gap of the cap layer 36 is wider than a band gap of the light-absorbing layer 32. A relative dielectric constant of the cap layer 36 is smaller than a relative dielectric constant of the light-absorbing layer 32.

The semiconductor layer 38 is formed of, for example, (p−)-AlInAs. The thickness of the semiconductor layer 38 is, for example, 200 nm. The semiconductor layer 38 is doped with, for example, Be. An impurity concentration is, for example, 1.0×10¹⁸ cm⁻³. The contact layer 40 is formed of, for example, (p+)-InGaAs. The thickness of the contact layer 40 is, for example, 200 nm. The contact layer 40 is doped with, for example, Be. An impurity concentration is, for example, 1.5×10¹⁹ cm⁻³. A lattice mismatch of the semiconductor layer is ±300 arcsec or less in the half width of a rocking curve. The semiconductor layer of the light receiving device 100 may be formed of a compound semiconductor other than the above.

The insulation film 42 is a passivation film and is formed of an insulator such as silicon nitride (SiN). The thickness of the insulation film 42 is, for example, 100 nm to 1000 nm. The electrode 12 and the electrode 14 are formed of metal.

### (Manufacturing Method)

For example, the semiconductor layer 22 to the contact layer 40 are epitaxially grown in order on one surface of the substrate 20 by metal organic chemical vapor deposition (MOCVD). Impurities can be added by supplying the impurities together with the source gas.

The mesa 13 is formed by etching from the contact layer 40 to the part of the substrate 20. The mesa 10 is formed by etching portions of the semiconductor layer 38 and the cap layer 36. Etching is performed to form the contact layer 40 into a ring shape. The insulation film 42 is formed by plasma enhanced chemical vapor deposition (plasma CVD). By etching, openings are formed in the parts of the insulation film 42 covering the top surface of the mesa 10 and the top surface of the substrate 20. The electrode 12 and the electrode 14 are formed by vacuum deposition and lift-off. The light receiving device 100 is formed.

The light receiving device 100 detects light such as infrared light. In the case of using the light receiving device 100, a positive voltage is applied to the electrode 12, and a negative voltage is applied to the electrode 14. In the part where the mesa 10 is provided, the n-type semiconductor layer 22, the i-type light-absorbing layer 32, the p-type semiconductor layer 38, and the contact layer 40 are arranged to form a positive-intrinsic-negative (pin) junction. A depletion layer spreads in the mesa 10. Light incident from the light receiving region 11 is absorbed by the light-absorbing layer 32. The light-absorbing layer 32 generates carriers (electron-hole pairs) by absorbing light. Due to the electric field applied to the depletion layer, carriers move and are output as photocurrent. The light receiving device 100 is an avalanche photodiode. The electrons collide with atoms in the multiplication layer 26, and thus more carriers are generated. This improves the sensitivity.

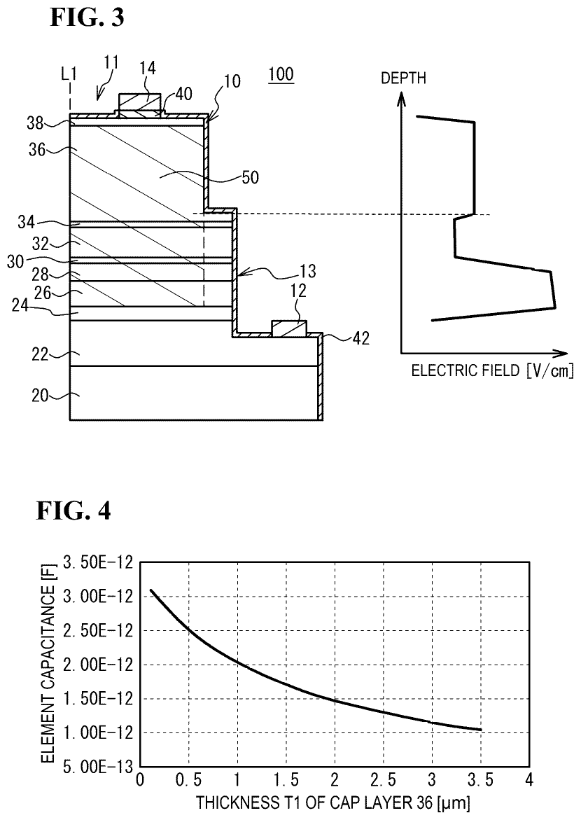

FIG. 3 is the cross-sectional view illustrating the light receiving device 100, showing the right half. FIG. 3 also shows the schematic of the electric field distribution corresponding to the stacked structure of the light receiving device 100.

In FIG. 3, a part of the hatching is omitted, and a depletion layer 50 is shown with oblique lines. By applying a reverse bias voltage, the depletion layer 50 is generated in a range inside the dashed line. The depletion layer 50 spreads within a range of the mesa 10 in the XY plane, extending from the multiplication layer 26 to the cap layer 36 in the Z axis direction, and may extend to the semiconductor layer 38.

The electric field distribution of FIG. 3 represents the electric field near the center (at the position of a line L1) of the light receiving device 100. The vertical axis represents the depth of the light receiving device 100 in the Z axis direction. The horizontal axis represents electric field strength. The high electric field is applied to the multiplication layer 26. The higher electric field is applied to the part of the cap layer 36 included in the mesa 10 than to the light-absorbing layer 32. The electric field attenuates from the cap layer 36 toward the light-absorbing layer 32.

In the case of the cap layer 36 being thin, for example, less than 1.0 μm, a high electric field is leaked from the cap layer 36 to the light-absorbing layer 32.

The electric field is applied to the light-absorbing layer 32 having a narrow band gap, and thus a tunnel current increases. In the first embodiment, as shown in FIG. 3, a high electric field is applied to the thick cap layer 36. The electric field is dispersed on the side surface of the cap layer 36 (the side surface of the mesa 10). The electric field applied to the light-absorbing layer 32 and the like located below the cap layer 36 is reduced. The electric field distribution of the light-absorbing layer 32 is uniformed, and the electric field is less likely to be concentrated. The tunnel current can be reduced.

In order to increase the light receiving sensitivity, the diameter D3 of the light receiving region 11 may be increased. In order for the light receiving device 100 to operate at high frequencies, it will suffice to decrease the element capacitance. However, expanding the light receiving region 11 increases the size of mesa 10 and increases the element capacitance. An element capacitance C is determined by an area S of the mesa 10, a thickness d of the depletion layer 50, and a relative dielectric constant ε of the depletion layer 50, and is calculated by the following equation.

C=εS/d (1)

The area S of the mesa 10 is determined according to the required light receiving sensitivity, and is, for example, several tens of thousands of μm². As the depletion layer 50 spreads in the Z axis direction, the thickness d increases and the capacitance C decreases. The relative dielectric constant ε depends on the semiconductor layer to be depleted. As shown in FIG. 3, since the cap layer 36 is thick, the thickness and the relative dielectric constant of the cap layer 36 affect the capacitance C.

The cap layer 36 is thicker than the light-absorbing layer 32 and is the thickest of the semiconductor layers of the light receiving device 100. The d in equation (1) increases, resulting in a decrease in the capacitance C, as the thick cap layer 36 becomes depleted. The cap layer 36 is formed of AlInAs and has the relative dielectric constant smaller than that of the light-absorbing layer 32. The ε in the equation (1) decreases, and the capacitance C decreases.

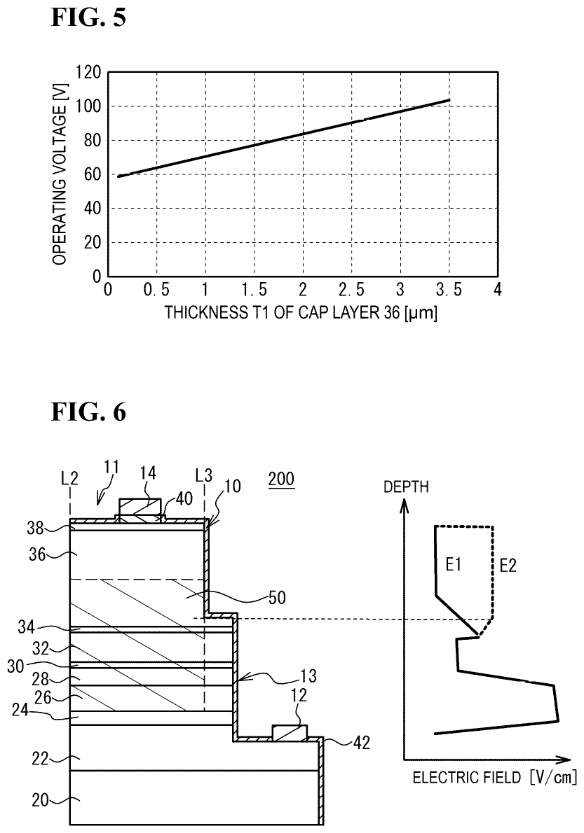

FIG. 4 is a diagram illustrating the capacitance of the light receiving device 100. The horizontal axis represents the thickness of the cap layer 36. The vertical axis represents the calculation result of the capacitance (element capacitance) of the light receiving device 100. FIG. 5 is a diagram illustrating the operating voltage of the light receiving device 100. The horizontal axis represents the thickness of the cap layer 36. The vertical axis represents the calculation result of the operating voltage of the light receiving device 100.

As shown in FIG. 4, the capacitance decreases as the cap layer 36 becomes thicker. Meanwhile, the thicker the cap layer 36 is, the higher the voltage for depletion is. As shown in FIG. 5, the operating voltage of the light receiving device 100 is increased, and the power consumption is increased.

As shown in FIG. 4, with the thickness T1 of 1.0 μm or more on the cap layer 36, the capacitance can be set to about 2.0×10⁻¹² F or less. As shown in FIG. 5, with the thickness T1 is 3.4 μm or more, the operating voltage is larger than 100 V.

In order to set the capacitance about 2.0×10⁻¹² F or less and the operating voltage 100 V or less, the thickness of the cap layer 36 is set to be 1.0 μm to 3.4 μm. The capacitance is about 2.0×10⁻¹² F or less and 1.0×10⁻¹² F or more. The operating voltage is about 70 V to 100 V.

According to the first embodiment, the cap layer 36 forms the mesa 10 and is thicker than the light-absorbing layer 32. The capacitance of the light receiving device 100 decreases as the thick cap layer 36 becomes depleted. Since the cap layer 36 is thick, the electric field is dispersed to the side surface of the cap layer 36. By dispersing the electric field in the Z axis direction, the electric field applied to the light-absorbing layer 32 and other layers located below the cap layer 36 is reduced. The electric field distribution of the light-absorbing layer 32 is uniformed, and the electric field is less likely to be concentrated. The tunnel current can be reduced. It is possible to decrease the capacitance and reduce the electric field.

The thickness T1 of the cap layer 36 may be 1.0 μm to 3.4 μm. As shown in FIG. 4, the capacitance is about 2.0×10⁻¹² F or less and 1.0×10⁻¹² F or more. As shown in FIG. 5, the operating voltage is about 70 V to 100 V. Both the capacitance and the operating voltage can be decreased, and the power consumption can be lowered.

The thickness T1 may be 1.0 μm or more, 2.0 μm or more, and 2.5 μm or less, 3.0 μm or less, or 3.4 μm or less. For example, by setting the thickness T1 to 2.0 μm or more, the capacitance becomes about 1.5×10⁻¹² F or less. By setting the thickness T1 to 2.5 μm or less, the operating voltage becomes 90 V or less.

The cap layer 36 is undoped, and an impurity concentration is, for example, 1.0×10¹⁵ cm⁻³ order or less. By applying a voltage to the undoped cap layer 36, the depletion layer 50 spreads in the Z axis direction, for example, from the multiplication layer 26 to the vicinity of the top surface of the cap layer 36. The capacitance of the light receiving device 100 can be decreased. Since the electric field is dispersed to the side surface of the cap layer 36, the concentration of the electric field in the light-absorbing layer 32 may be reduced.

The light receiving device 100 has the mesa 10 and the mesa 13. The elements are separated by the mesa 10 and the mesa 13. The mesa 10 includes a center portion of the cap layer 36 and the semiconductor layer 38. The mesa 13 includes the outer peripheral portion of the cap layer 36 and includes a part from the current diffusion layer 34 to the substrate 20. The cap layer 36 is thick and occupies most of the mesa 10. The electric field is dispersed on the side surface of the mesa 10 and is less likely to concentrate below the mesa 10. The electric field distribution of the light-absorbing layer 32 is uniformed, and the electric field is less likely to be concentrated. The tunnel current can be reduced.

The light-absorbing layer 32 is formed of InGaAs. The cap layer 36 is formed of AlInAs and has the wider band gap than the light-absorbing layer 32. By dispersing the electric field to the thick cap layer 36, the electric field applied to the light-absorbing layer 32 having a low band gap is reduced. The tunnel current becomes smaller. In the cap layer 36 having the wide band gap, the tunnel effect is unlikely to occur, and the dark current decreases.

The n-type semiconductor layer 22 and the semiconductor layer 24, the light-absorbing layer 32, the p-type semiconductor layer 38, and the contact layer 40 are stacked on to form the pin junction. The thick cap layer 36 is provided between the light-absorbing layer 32 and the semiconductor layer 38, thereby decreasing the capacitance and the electric field strength. The p-type semiconductor layer may be stacked between the substrate 20 and the light-absorbing layer 32, and the n-type semiconductor layer may be stacked on the cap layer 36.

The light receiving device 100 is the avalanche photodiode and has the multiplication layer 26. As described above, by setting the thickness T1 of the cap layer 36 to be in an appropriate range, the operating voltage can be set to be, for example, 100 V or less. The sensitivity can be increased by setting the diameter D3 of the light receiving region 11 to, for example, 200 μm or more. The capacitance can be reduced as the thick cap layer 36 becomes depleted. The light receiving device 100 may be a photodiode other than the avalanche photodiode.

### Second Embodiment

FIG. 6 is a cross-sectional view illustrating a light receiving device 200 according to the second embodiment, and shows the right half as in FIG. 3. The electric field distribution is also shown in FIG. 6. The description of the same configuration as that of the first embodiment will be omitted. A cap layer 36 of the light receiving device 200 is formed of, for example, (p−)-AlInAs. The cap layer 36 is doped with, for example, Be. The impurity concentration of the cap layer 36 is lower than the impurity concentration of a semiconductor layer 38 and a contact layer 40, and is, for example, 1.0×10¹⁶ cm⁻³. The cap layer 36 is thicker than a light-absorbing layer 32. The thickness of the cap layer 36 is, for example, 2500 nm. A band gap of the cap layer 36 is wider than a band gap of the light-absorbing layer 32.

Since the cap layer 36 is of the (p⁻)-type, a depletion layer 50 is thinner than the depletion layer of the first embodiment in the Z axis direction. For example, the depletion layer 50 extends from the middle of the cap layer 36 to the multiplication layer 26.

In the electric field distribution diagram of FIG. 6, the solid line represents an electric field strength E1 applied near the center of the light receiving device 200 (at the position of a line L2). The dotted line represents an electric field strength E2 applied to the side surface (at the position of a line L3) of a mesa 10. From the multiplication layer 26 to the light-absorbing layer 32, the electric field strength E1 at the center position is the same as the electric field strength E2 at the position of the side surface of the mesa 10.

The cap layer 36 is depleted in a part close to the light-absorbing layer 32 in the Z axis direction, and is not depleted in a part close to the top surface. The electric field strength E1 at the center position (the line L2) is small in the part close to the top surface of the cap layer 36, and increases as the distance from the light-absorbing layer 32 decreases. Meanwhile, the electric field strength E2 applied to the side surface of the cap layer 36 (the side surface of the mesa 10) is higher than the electric field strength E1 applied to the center. The electric field strength E2 is attenuated upon reaching the light-absorbing layer 32, and becomes approximately equal to the electric field strength E1.

Since the mesa 10 is formed of the (p⁻)-type cap layer 36, a high electric field is uniformly applied to the side surface of the mesa 10. Thus, the electric field is dispersed, and the electric field applied to the light-absorbing layer 32 is reduced. The tunnel current is reduced.

FIG. 7 is a diagram illustrating electric field strength. The horizontal axis represents an impurity concentration of the cap layer 36. The vertical axis represents the calculation result of the electric field strength (edge electric field strength) E2 on the side surface of the mesa 10. The higher the impurity concentration, the lower the electric field strength. In the case of the impurity concentration is 5.0×10¹⁵ cm⁻³ or less, the electric field strength is 3.0×10⁵ V/cm or less.

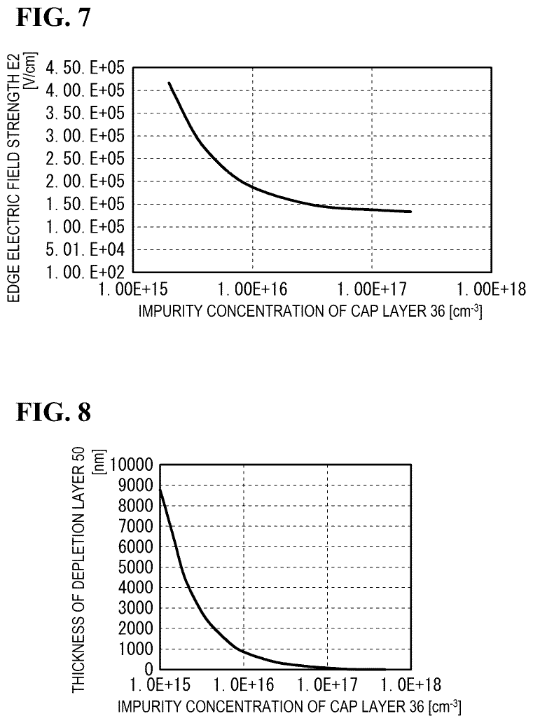

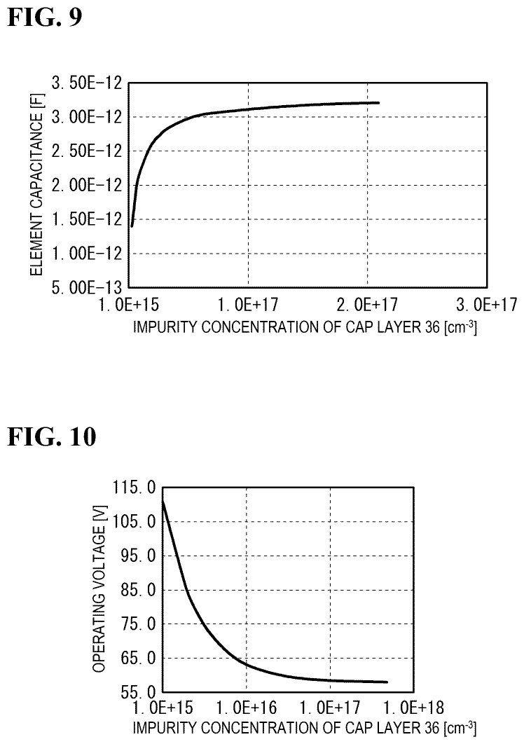

FIG. 8 is a diagram illustrating the thickness of the depletion layer 50. The horizontal axis represents the impurity concentration of the cap layer 36. The vertical axis represents the calculation result of the thickness of the depletion layer 50 in the cap layer 36. FIG. 9 is a diagram illustrating the capacitance of the light receiving device 200. The horizontal axis represents the impurity concentration of the cap layer 36. The vertical axis represents the calculation result of the capacitance of the light receiving device 200. FIG. 10 is a diagram illustrating the operating voltage of the light receiving device 200. The horizontal axis represents the impurity concentration of the cap layer 36. The vertical axis represents the calculation result of the operating voltage of the light receiving device 200.

As the impurity concentration is lower, the depletion layer 50 becomes thicker, and the capacitance decreases. The operating voltage is increased. As the impurity concentration increases, the depletion layer 50 becomes thinner, and the capacitance increases. The operating voltage is lowered.

As shown in FIG. 10, in order to make the operating voltage 115 V or less, the impurity concentration may set to be 1.0×10¹⁵ cm⁻³ or more. As shown in FIG. 8 and FIG. 9, in order to widen the depletion layer 50 and decrease the capacitance, the impurity concentration may be set to, for example, 1.0×10¹⁷ cm⁻³ or less. That is, by setting the impurity concentration to, for example, 1.0×10¹⁵ cm⁻³ to 1.0×10¹⁷ cm⁻³, both the operating voltage and the capacitance can be decreased. The impurity concentration may be, for example, 5.0×10¹⁵ cm⁻³ to 5.0×10¹⁶ cm⁻³. As shown in FIG. 10, the operating voltage can be set to 75 V or less. The capacitance can be set to 3.0×10⁻¹² F or less. As shown in FIG. 8, in the case where the impurity concentration ranges from 5.0×10¹⁵ cm⁻³ to 7.0×10¹⁵ cm⁻³, the thickness of the depletion layer 50 is about 2000 nm to 2500 nm. Most of the cap layer 36 is depleted.

According to the second embodiment, the cap layer 36 forms the mesa 10 and is thicker than the light-absorbing layer 32. The capacitance of the light receiving device 200 decreases as the thick cap layer 36 becomes depleted. Since the cap layer 36 is thick, the electric field is dispersed to the side surface of the cap layer 36. As shown in FIG. 6, since the cap layer 36 is (p⁻)-type, the electric field is uniformly applied to the side surface. An electric field applied to the light-absorbing layer 32 and the like located below the cap layer 36 is reduced. It is possible to decrease the capacitance and reduce the electric field.

The impurity concentration of the cap layer 36 is lower than the impurity concentrations of the semiconductor layer 38 and the contact layer 40, and is, for example, 1.0×10¹⁵ cm⁻³ to 1.0×10¹⁷ cm⁻³. The operating voltage and capacitance can be decreased. Since the electric field is dispersed over the side surface of the mesa 10, the electric field strength also decreases. The electric field applied to the cap layer 36 is reduced, and the voltage is also reduced. Power consumption is lowered.

The first embodiment and the second embodiment may be applied to an array-type light receiving device. In the array-type light receiving device, a plurality of mesas are arranged, for example, in a two dimensional grid pattern. A pair of one mesa 10 and one mesa 13 functions as one photodiode. The photodiodes are separated by the recesses between the mesas. The first embodiment or the second embodiment is applied to each of the plurality of mesa.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving device comprising:
a first semiconductor layer having a first conductivity type;
a light-absorbing layer stacked over a surface of the first semiconductor layer;
a second semiconductor layer stacked over a surface of the light-absorbing layer opposite to the first semiconductor layer;
a third semiconductor layer stacked on a surface of the second semiconductor layer opposite to the light-absorbing layer and having a second conductivity type;
a first electrode electrically connected to the first semiconductor layer; and
a second electrode electrically connected to the third semiconductor layer,
wherein the second semiconductor layer is configured to form a mesa and is thicker than the light-absorbing layer.

2. The light receiving device according to claim 1, wherein the second semiconductor layer has a thickness of 1.0 μm to 3.4 μm.

3. The light receiving device according to claim 1, wherein the second semiconductor layer is undoped.

4. The light receiving device according to claim 1,
wherein the second semiconductor layer has the second conductivity type, and
the second semiconductor layer has an impurity concentration lower than an impurity concentration of the third semiconductor layer.

5. The light receiving device according to claim 4, wherein the second semiconductor layer has an impurity concentration of 1.0×10¹⁵ cm⁻³ to 1.0×10¹⁷ cm⁻³.

6. The light receiving device according to claim 1,
wherein the second semiconductor layer includes a first portion and a second portion,
the first portion of the second semiconductor layer is configured to form the mesa, and
the second portion of the second semiconductor layer, the light-absorbing layer, and the first semiconductor layer are located below the mesa and outside the mesa.

7. The light receiving device according to claim 1,
wherein the light-absorbing layer is formed of indium gallium arsenide, and
the second semiconductor layer is formed of aluminum indium arsenide.

8. The light receiving device according to claim 1,
wherein the light receiving device is an avalanche photodiode, and
the light receiving device includes a multiplication layer stacked below the light-absorbing layer.
